(19) United States
(12) Patent Application Publication
(10) Pub. No.: US 2011/0003083 A1
(43) Pub. Date: Jan. 6, 2011

(54) Method for making functional ceramic films on ceramic materials

(76) Inventors: Quanzu Yang, Vancouver (CA); Donghui Lu, Vancouver (CA)

Correspondence Address: TODD N. HATHAWAY, 119 N. COMMERCIAL ST. #620, BELLINGHAM, WA, 98225, US

(21) Appl. No.: 12/798,924

(22) Filed: Apr. 13, 2010

Related U.S. Application Data
(60) Provisional application No. 61/212,516, filed on Apr. 13, 2009.

(51) Int. Cl. C23C 4/10; B05D 3/02; B05D 1/02; B05D 3/12; B05D 1/18; C23C 16/06; B05D 1/28; B05D 1/12; B05D 1/08

(52) U.S. Cl. 427/453; 427/372.2; 427/421.1; 427/240; 427/430.1; 427/248.1; 427/429; 427/190; 427/595

(57) ABSTRACT

A method for forming functional ceramic films on ceramic materials, to enhance mechanical properties, chemical stability, and/or biological properties of the materials. The functional ceramic film comprises at least about 10 weight percent pure zirconia, with phase transformation at tetragonal/cubic phases at high temperature to monoclinic phase at room temperature, leading to volume expansion and compressive stress. The compressive stress enhances mechanical strength, wear resistance, hardness and other properties, and also tends to eliminate cracks and flaws in the ceramic material. The functional film may also include bioactive materials, and may include a structure for eluting drugs so as to serve as a drug delivery vehicle. The functional ceramic films may be centered on the base ceramic, or the materials may be co-centered. Devices having the ceramic materials with functional films may be used, for various medical or dental purposes. Alternatively, the ceramics and films may be tailored for use in engineering or industrial applications, or as armor.

### RELATED APPLICATIONS

This application claims the benefit of U.S. Provisional Patent Application Ser. No. 61/212,516 filed on Apr. 13, 2009.

### FIELD OF THE INVENTION

Present invention relates generally to ceramic materials, and, more particularly to a method for making functional ceramic films on ceramic materials for enhancing mechanical properties, chemical stability, and/or biological properties.

### BACKGROUND

Zirconium dioxide (Zirconia) is one of the industrial ceramic materials for engineering applications and medical devices. Pure ZrO₂ has a monoclinic crystal structure at room temperature and transitions to tetragonal and cubic at increasing temperatures. The volume expansion caused by the cubic to tetragonal to monoclinic transformation induces very large stresses, and will cause pure ZrO₂ to crack upon cooling from high temperatures. Several different oxides are added to zirconia to stabilize the tetragonal and/or cubic phases: magnesium oxide (MgO), yttrinum oxide, (Y₂O₃), calcium oxide (CaO), and cerium(III) oxide (Ce₂O₃), ceria, dysprosia, gadolinia and lanthana amongst others (Seiji Ban, “Reliability and properties of core materials for all-ceramic dental restorations” Japanese Dental Science Review (2008) 44, 3-21).

Zirconia is well used in its ‘stabilized’ state. In some cases, the tetragonal phase can be metastable by adding second phase materials. If sufficient quantities of the metastable tetragonal phase are present, then an applied stress, magnified by the stress concentration at a crack tip, can cause the tetragonal phase to convert to monoclinic, with the associated volume expansion. This phase transformation can then put the crack into compression, retarding its growth, and enhancing the fracture toughness. This mechanism is known as transformation toughening, and significantly extends the reliability and lifetime of products made with stabilized zirconia. A special case of zirconia is that of tetragonal zirconia polycrystalline or TZP, which is indicative of polycrystalline zirconia composed of only the metastable tetragonal phase.

Zirconia is commonly used for medical device applications, such as orthopedics and dentals. Today, more than 600,000 zirconia femoral heads have been implanted worldwide, mainly in the US and in Europe. However, mainly due to issues of low temperature degradation of stabilized zirconia, roughly 400 biomedical grade zirconia femoral heads failed in a very short period in 2001. When stabilized with yttria, zirconia ceramics can retain their high temperature tetragonal structure, which is metastable at room temperature. Ageing occurs by a slow surface transformation to the stable monoclinic phase in the presence of water or water vapor. Transformation starts first in isolated grains on the surface by a stress corrosion type mechanism. For a femoral head, surface means the polished wearing surface, but also the interior of the cone, in contact with the metallic taper. The nucleation of the transformation leads then to a cascade of events occurring neighbor to neighbor: the transformation of one grain leads to a volume increase stressing up the neighboring grains and to microcracking. This offers a path for the water to penetrate down into the specimen. The growth stage again depends of several microstructure patterns: porosity, residual stresses, grain size, etc. It is quite clear at this stage that both nucleation and growth will be highly process related. (Chevalier, “What future for zirconia as a biomaterial?” Biomaterials 27 (2006) 535-543)

### TERMINOLOGY

For ease of understanding, particular terms used herein include the following:

Functional ceramic film refers to a film comprising at least about 10 weight percentage of pure zirconia with phase transformation from tetragonal/cubic phases at high temperature to monoclinic phase at room temperature to lead to volume expansion and compressive stress.
Pure zirconia refers to at least about 90 weight percentage of monoclinic zirconia at low temperature and/or un-stabilized zirconia exhibiting phase transformation from tetragonal/cubic phases at high temperature to monoclinic phase at room temperature leading lead to volume expansion.
Un-stabilized zirconia refers to phase transformation from tetragonal/cubic phases at high temperature to monoclinic phase at room temperature leading to volume expansion.
Monoclinic zirconia refers to zirconia having a monoclinic crystal structure.
Compressive stress refers to stress caused by the ceramic film volume expansion during the cooling process from sintering temperature.
Ceramic materials refers to inorganic, non-metallic solid compounds, including metal oxide, metal salts, composite, glasses and/or crystal structure materials, composite, polymer/ceramic composite, and mixtures of thereof.
Pre-firing refers to firing the ceramic materials at temperatures of about 200° C.-1400° C. to gain a degree of mechanical strength for handling, machining, shipping, and other purposes. The pre-firing temperature is lower than sintering temperatures.
Sintering refers to a method for making ceramic objects from powder, by heating the material at temperature below its melting point (solid state sintering) until its particles adhere to each other for densification. This temperature is called the sintering temperature. The sintering is traditionally used for manufacturing ceramic objects
Un-sintered ceramics (non-sintering ceramic) refers to ceramic materials formed without firing at sintering temperature. Un-sintered ceramics can include both pre-firing and non-pre-firing ceramic materials.
Co-sintering refers a process to sinter a functional ceramic film and ceramic materials simultaneously at sintering temperature.
Secondary phases refers to non-pure zirconia phase.
Dense structure refers to materials that have been fired at sintering temperature and that have been a porosity less than about 15 volume percent.
Nano-size refers to a particle size having at least one dimension less than about 140 nanometer.
Non-Zirconia refers to ceramic materials having zirconia content of less than about 10 weight percent.
Controlled release refers to materials or products that are formulated to release a bioactive ingredient gradually and predictably, for example, as clinical requirement.

### SUMMARY OF THE INVENTION

The present invention discloses a method for making a functional film on ceramic materials, for enhancing wear resistance, hardness, corrosion resistance, and biological properties. The functional film is formed on surfaces of the ceramic materials and has high mechanical strength, compressive stresses, and high chemical stability. In a broad sense, the method comprises forming at least one layer of functional ceramic film with compressive stress, that covers at least a portion of the surface of ceramic materials.

The functional ceramic film of the present invention comprises at least about 10 weight percentage of pure zirconia, with phase transformation from tetragonal/cubic phases at high temperature to monoclinic phase at room temperature to lead to volume expansion and compressive stress. The functional film covers at least a portion of the surface of the ceramic material. The ceramic material used in the present invention include, but are not limited to, metal oxide ceramic, non-oxide ceramic, ceramic composite. suitable oxide ceramic include zirconium oxide, aluminum oxide, silica oxide, Magnesium oxide, Iron oxide, calcium oxide, and mixtures of thereof.

The zirconia materials suitable for use in the present invention comprise at least a portion of zirconia, and include, but are not limited to, stabilized zirconia, partially stabilized zirconia, zirconia composite, and mixtures thereof. Compounds suitable to be used for stabilizing the zirconia include but not limited, to metal oxide, metal salts, magnesium oxide (MgO), yttrinum oxide, (Y₂O₃), calcium oxide (CaO), and cerium(III) oxide (Ce₂O₃), alumina oxide, silicon oxide, calcium silicate, copper oxide, iron oxide, nickel oxide, praseodymium oxide, titanium oxide, erbium oxide, europium oxide, holmium oxide, chromium oxide, manganese oxide, vanadium oxide, cobalt oxide, neodymium oxide amongst others and mixtures thereof. Zirconia composites include, but are not limited to, fiber composite, metal oxide composite, non-oxide composite, alumina/zirconia composite, and mixture thereof.

The ceramic film in the present invention comprises at least a portion of zirconia which has a cubic/tetragonal structure at high temperature and transition to a monoclinic crystal structure at decreasing temperatures. The volume expansion caused by the cubic/tetragonal to monoclinic transformation induces compressive stresses in the zirconia film which enhances the mechanical and biological properties.

Another embodiment of the present invention povides a multi-layer structure for optimizing the performance of ceramic materials. The multi-layer structure may comprise a first layer of ceramic film and the second layer of zirconia. The interfacial layers act as a compressive stress gradient layer to reduce interfacial stress. The interfacial layer can be partially stabilized zirconia or oxide ceramics.

In a preferred embodiment for medical device applications, a multi-layer structure in accordance with present invention comprises a first layer that includes a zirconia layer with compressive stress for enhancing mechanical properties and chemical stability, and a second layer that includes a bioactive layer for enhancing bioactivity and biocompatibility. Materials in the bioactive layer may include, but are not limited to, metal oxides, metal salts, calcium phosphate, hydroxyapatite, calcium silicates, titanium oxide, tantalum oxide, metal nitride, and mixtures thereof.

Another aspect in present invention is to deposit a porous layer as drug delivery vehicle for controlled release bioactive agents.

In another preferred embodiment, the ceramic layers are used to prevent the oxidation of non-oxide ceramics. For example, silicon nitride may have a layer of aluminum oxide deposited thereon, and the coated silicon nitride then sintered in a nitrogen furnace. The interface between alumina coating and silicon nitride form an alumina/silicate structure. The alumina layer will prevent from oxidation of silicon nitride. In another example, silicon carbon may be deposited on a pure-zirconia layer and fired in a helium gas atmosphere. The zirconia becomes monoclinic phase from cubic phase during the cooling process. The compressive stress of the zirconia layer increases the surface hardness, wear resistance, and oxygen barrier.

In another embodiment the ceramic film is deposited by one or more of a variety of processes, including, but not limited to, spraying, spinning, dipping, ultrasonic spraying, plasma spray, chemical and physical vapor depositions, brushing, hot spraying, powder spraying, and combinations thereof. A coating solution or slurry for making the functional ceramic film can be prepared, for example, by sol-gel process, composite sol-gel process, power slurry, polymer/zirconia powder slurry. Another process for making the ceramic film may be by co-pressing, including hot and cold isostatic pressing, for example. The ceramic materials with the zirconia layer may suitably be fired at temperatures from about 1000 to 2300° C.

The thickness of the ceramic film may be in the range from about 0.01 micrometer to 20 mm, preferable thickness in the range from about 1 micrometer to about 5 millimeter. The ceramic film comprises at least about 10% zirconia by weight percentage. The zirconia film may comprise secondary phases for improving t performance.

Significant advantages of zirconia ceramic materials with compressive zirconia film in accordance with the present invention include high mechanical strength, high fracture toughness, high hardness, high chemical resistance, and wear resistance. The ceramic materials with compressive ceramic films in accordance with the present invention may be used, for example, in orthopedic implants, dental materials, refractory materials, seals, valves, and pump impellers, optical and electronic applications.

### BRIEF DESCRIPTION OF THE DRAWINGS

FIG. 1 is a schematic cross-sectional view of a ceramic material coated with a compressive stress functional ceramic film in accordance with the present invention, in which the compressive stresses in the functional ceramic film enhance wear resistance, fracture toughness, chemical stability, bending strength, and hardness; the embodiment illustrated in FIG. 1 being eminently suited for engineering ceramic applications, such as arm ceramics, ceramic tools, seals, valves and pump impellers, for example;

FIG. 2 is a schematic cross-sectional view of a ceramic material having a multi-layer functional ceramic film structure of compressive stress film and bio-functional film in accordance with the present invention, in which the first layer on the ceramic material has compressive stress for improving the wear resistance, fracture toughness, chemical stability, bending strength, and hardness, and the second layer includes bioactive and biocompatible coatings for directly contacting with soft and hard tissues, multi-layer embodiment illustrated in FIG. 2 being eminently suited for use in biomedical applications, such dental implant and orthopedic applications; and

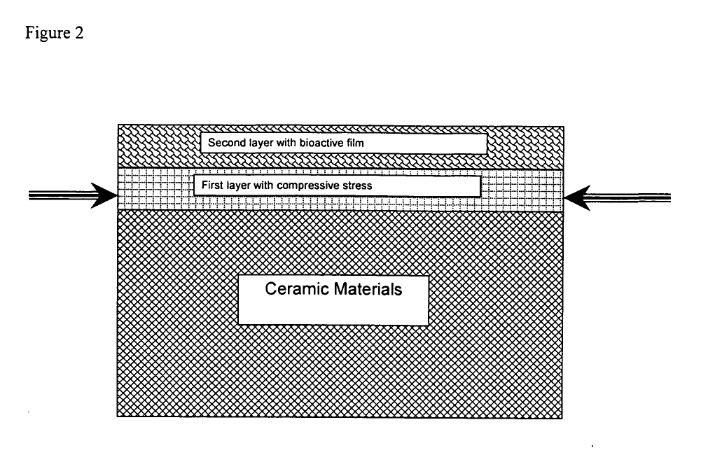

FIG. 3 is a schematic cross-sectional view of a ceramic material having a multi-layer functional ceramic film structure of a first layer with compressive stress film and a second, top layer of porous bioceramic coatings used as a drug delivery vehicle, the embodiment illustrated in FIG. 3 being eminently suited for use in for biomedical applications.

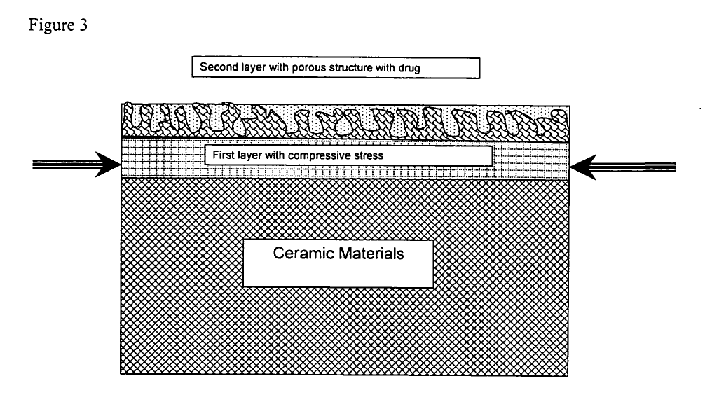

### DETAILED DESCRIPTION

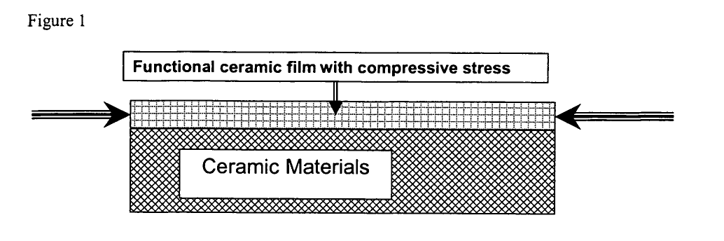

As noted above, the present invention discloses a process for making a functional film or films on ceramic materials for improving mechanical properties, with at least a portion of the surface of the ceramic material being covered by the functional ceramic film or films. The functional ceramic film has compressive stresses for enhancing mechanical strength, wear resistance, hardness, corrosion resistance, chemical stability, fracture toughness, and biological properties. Also, compressive stresses in the ceramic tend to eliminate surface flaws by pressing closed cracks and defects with the retained compressive forces, while the core ceramic materials remain relatively free of the defects. An example of such ceramic material having a functional ceramic coating is shown in FIG. 1.

The functional ceramic film comprises at least one portion of substantially pure zirconia ceramic having a cubic/tetragonal structure at high temperature and a transition to a monoclinic crystal structure at decreasing temperatures. The volume expansion in the functional ceramic film caused by the pure zirconia (un-stabilized zirconia) phase transformation from cubic/tetragonal at high temperature to monoclinic structure at low temperature induces compressive stresses which enhance the mechanical and biological properties of the ceramic materials. The pure zirconia exhibiting phase transformation is excluded in the functional ceramic film in an amount of at least about 10 weight percentage of the total ceramic film. The thickness of the functional ceramic film is suitably in the range from about 0.01 micrometer to about 20 millimeter, preferable in the range from about 0.1 micrometer to 1 millimeter.

In a preferred embodiment, a secondary phase can be incorporated into the composition of the functional film, such as fibers, aggregates, bioglasses, bioceramics, polymers, and metals, for example, in variety of morphological forms such as particles, fibers, loops, liquids, and others. The compounds in the secondary phase may include, at are not limited to, metal oxides, metal salts, glasses, non-oxides. The metal oxides may include, but are not limited to, magnesium oxide (MgO), yttrinum oxide, (Y₂O₃), calcium oxide (CaO), and cerium(III) oxide (Ce₂O₃), alumina oxide, silicon oxide, calcium silicate, copper oxide, iron oxide, nickel oxide, praseodymium oxide, titanium oxide, erbium oxide, europium oxide, holmium oxide, chromium oxide, manganese oxide, vanadium oxide, cobalt oxide, neodymium oxide, amongst others, and mixtures thereof. The zirconia composites include, but are not limited to, fiber composites, metal oxide composites, non-oxide composites, fiber ceramic composites, zirconia/titanium nitride composites, zirconia/silicon carbon composites, zirconia/silicon nitride composites, alumia/zirconia composites, and mixtures thereof.

In another aspect, the functional film may include the secondary phase in order to modify the compressive stress for different applications. For example, a mixture of 60 wt % pure zirconia particles (particle size 10-20 micrometer) and 40 wt % of nanosize alumina was used for making the functional film on un-sintered alumina armor plates, and the film and ceramic materials were then fired at 1400° C. for 1.5 hour. The zirconia partially remains in monoclinic phase with the phase transformation for leading to the compressive stress. The compressive stress with secondary phase included was therefore lower than in the case of a pure zirconia functional film. The relatively large particles (aggregation particles) of pure zirconia can be made by spraying a pure nano-zirconia powder slurry.

In a further aspect of the present invention, a core/shell composite structure can be used for modifying the compressive stress in the coating film. The core/shell composite structures include at least one portion of pure zirconia in the core and at least one component of the substrate in the shell structure. The pure zirconia in the core produces the compressive stress in the coating layer during the cooling process from high sintering temperatures, and the shell of composite forms a strong bond with the ceramic substrate.

In another embodiment, the multi-layer coatings are used for modifying compressive stress in the coating film. The multi-layer coating in this case comprises less pure zirconia in the first layer than in the second coating layer. As a result, the compressive stress gradually increases from the first layer to the second layer. An example of a ceramic material having multiple layers forming a functional ceramic coating is shown in FIG. 1.

Ceramic materials suitable for use in the present invention include, but are not limited to, metal oxides, metal salts, non-oxide ceramics, and mixtures of thereof. Suitable metal oxide ceramics include, but are not limited to antimony oxide, cobalte oxide, iron oxide, lead oxide, manganese oxide, silver oxide, copper oxide, dicarbon monoxide, potassium oxide, rubidium oxide, thallium oxide, sodium oxide, aluminium oxide, barium oxide, beryllium oxide, cadmium oxide, calcium oxide, palladium oxide, strontium oxide, sulphur oxide, tin oxide, titanium oxide, vanadium oxide, zinc oxide, antimony oxide, arsenic oxide, bismuth oxide, boron oxide, chromium oxide, erbium oxide, gadolinium oxide, gallium oxide, holmium oxide, indium oxide, lanthanum oxide, nickel oxide, titanium oxide, tungsten oxide, vanadium oxide, ytterbium oxide, yttrium(III) oxide, and mixtures of thereof. Suitable metal salts include, but are not limited to, metal silicates, metal aluminates, and mixture thereof. Suitable non-oxide ceramics include, but are not limited to, carbide ceramics, nitride ceramics, and mixtures of thereof, for examples, silicon carbides, aluminum carbides, titanium carbides, boron carbide carbides, titanium carbides, chromium carbides, silicon nitrides, aluminum nitrides, titanium nitrides, boron carbide nitrides, titanium nitrides, chromium nitrides, and mixtures thereof. suitable metal salts ention include, but are not limited to, dalts of antimony, cobalt, iron, lead, manganese, silver, copper, dicarbon, potassium, rubidium, thallium, sodium, aluminium, barium, beryllium, cadmium, calcium, palladium, strontium, sulphur, tin, titanium, vanadium, zinc, antimony, arsenic, bismuth, boron, chromium, erbium, gadolinium, gallium, holmium, indium, lanthanum, nickel, titanium, tungsten vanadium, ytterbium, yttrium, and mixtures thereof.

Additional suitable ceramic materials ntion include composites of oxide ceramics/oxide ceramics, metal/oxide ceramics, metal/non-oxide ceramics, oxide ceramics/non-oxide ceramics, mullite, spinal, and non-oxide ceramics/non-oxide ceramics, for example, alumina/zirconia, alumina/silicon carbide, and silicon carbon/aluminum nitride. The composites may be employed in the form of fiber/powder, powder/powder, and fiber/fiber composites.

The zirconia ceramics comprise at least one portion of zirconia ceramics, including, but not limited to, stabilized zirconia, partially stabilized zirconia, zirconia composites, zirconia compounds, and mixtures thereof. Chemical compounds suitable for stabilizing the zirconia include, but are not limited to, metal oxides, metal salts, metals, non-oxide ceramic materials, and mixtures thereof. Suitable metal oxides include, but are not limited to, magnesium oxide (MgO), yttrinum oxide, (Y₂O₃), calcium oxide (CaO), cerium(III) oxide (Ce₂O₃), aluminum oxide, silicon oxide, calcium silicate, copper oxide, iron oxide, nickel oxide, praseodymium oxide, titanium oxide, erbium oxide, europium oxide, holmium oxide, chromium oxide, manganese oxide, vanadium oxide, cobalt oxide, neodymium oxide, amongst others, and mixtures thereof. Forms of zirconia composites suitable for use include, but are not limited to, fiber composites, metal oxide composites, non-oxide composites, fiber ceramic composites, zirconia/titanium nitride composites, zirconia/silicon carbon composites, zirconia/silicon nitride composites, zirconia/, alumia/zirconia composites, and mixtures thereof.

The ceramic materials of the present invention are suitably formed by a variety of processes, including, but not limited to, gel-casting, slip casting, tape-casting, powder pressing, hot pressing, cold pressing, machining, and combinations thereof. The functional ceramic films are suitably deposited on at least a portion of the surface of the ceramic materials by a variety of processes, including, but not limited to, spraying, casting, dipping, spinning, y, brushing, ultrasonic spraying, screen printing, plasma spraying, sputter process, electric deposition, physical process deposition, chemical process deposition, co-pressing formation (cold pressing and hot pressing processes) and combinations thereof. The ceramic particle size used for making functional film is suitably in the range of about 1 nanometer-500 micrometers. The ceramic materials with functional film are suitably sintered at temperatures in the range of about 600° C.-2700° C. The functional ceramic film comprises at least about 10 wt % of zirconia. The interfacial bonding strength of the functional film on ceramic material substrate is normally at least 50 MPa.

In one aspect, the functional ceramic film is directly deposited on the un-sintered ceramic substrate, with the material then being co-sintered at temperature in the range of about 600° C.-2700° C., preferably in the range of about 900° C.-1700° C. The advantages of the co-sintering (co-firing) process is simultaneous densification of the functional ceramic film and the ceramic substrate to avoid un-matching sintering shrinkages causing coating film cracks and damage of the interface. Therefore, the bonding strength of functional ceramic film to the substrate of ceramic materials are significantly enhanced and defects of the coatings and interfacial structures are reduced. By using the co-sintering process, it is possible for the functional ceramic film with ceramic materials to form ceramic bonding as one unit.

In another aspect, the ceramic materials are pre-fired at temperatures of about 200° C.-1400° C. to gain some mechanical strength, for example for handling, machining, and/or shipping. The pre-firing temperature is lower than sintering temperatures. The functional ceramic film can be deposited on pre-fired ceramic materials substrate, and the functional ceramic film and ceramic materials are then fired at sintering temperature for densification.

In some embodiments, nano-size particles can be used for making the functional films on ceramic materials for reduced sintering temperatures. The nanosize particles of ceramic suitably having sizes in the range of about 1 nanometers-500 nanometers, preferably in the range of about 10 nanometers-200 nanometers.

In another aspect, the zirconia composite coatings can be used for non-zirconia ceramic materials applications. The zirconia composite coatings can be used to improve the interfacial bonding on non-zirconia substrates. The pure zirconia portion can be used as a reinforcement phase for the composite coating, and the matrix phase of the composite coating layer can include at least one chemical component of the non-zirconia ceramic material in order to form a high strength bond with the substrate. The zirconia reinforcement phase results in the compressive stress in composite coatings during the cooling process from high sintering temperature.

In a material aspect core/shell composite materials are used for coating applications. The core/shell composite comprises at least one portion of substantially pure zirconia in inside the core structure, and at least one chemical component of the substrate of non-zirconia materials. The pure zirconia portion of the core expands and produces, the compressive stress in the coating layer, and the shell of composite forms a strong bond with the ceramic substrate.

A discussed above with regard to medical device applications, stabilized zirconia ceramics have t excellent mechanical properties, however the aging issues of stabilized zirconia have heretofore compromised the success of such ceramics in medical devices. When stabilized zirconia ceramics can retain their high-temperature tetragonal structure, it is metastable at room temperature. Ageing occurs by a slow surface transformation to the stable monoclinic phase in the presence of water or water vapor. Transformation starts first in isolated grains on the surface by a stress corrosion type mechanism. However, the monoclinic structure of zirconia is very stable in water or vapor water environments. In a preferred embodiment, the present invention provides a process for making a zirconia protection layer on the surface of a stabilized zirconia medical device, by a co-pressing or coating process followed by co-sintering at high temperature. The functional film of zirconia will have the phase transformation from cubic structure to tetragonal structure, and then to room temperature monoclinic structure during the process of cooling from sintering temperature to room temperature. At the same time, the volume of the layer containing pure zirconia layer is increasing by 0.1%-15%, which results in the compressive stress on the surface. Therefore, the monoclinic zirconia layer will enhance the mechanical properties of the stabilized zirconia, such as surface hardness, wear resistance, bending strength, and corrosion resistance. The compressive stress on the surface also reduces surface defects and cracks, somewhat is similar to tempered glasses. Another advantage is that monoclinic zirconia is very chemical stable against water or water vapor environments. The main aging issues of stabilized zirconia for medical applications are thus solved.

Medical devices to which the present invention is applicable include, but are not limited to, bone implants, dental implants, reconstructing arthritic or fractured joints (artificial hips, knees, femoral head, shoulders, elbows, and wrists), components for repairing fractures (bone plates, screws, wires), components for correcting chronic spinal curvature (harrington rods), devices replacing missing extremities (e.g., permanently implanted artificial limbs), devices for immobilizing vertebrae to protect the spinal cord (e.g., spinal fusion), devices for restoring the alveolar ridge to improve denture fit (e.g., alveolar bone replacements, mandibular reconstruction), devices for replacing diseased, damaged or loosened teeth e.g., end osseous tooth replacement implants, dental poster, dental crown), posts for stress applications required to change deformities (e.g., orthopedic anchors), surgical tools, and combinations thereof.

In another embodiment of the present invention, a functional zirconia film is deposited on the surfaces of zirconia/alumina composite materials, alumina ceramics, mullite ceramics an spinal ceramics, by, for example, spraying, dipping, spinning, and brushing. The coated zirconia/alumina composite is fired at about 600° C.-2000° C. The zirconia film forms a strong bond with the zirconia/alumina composite, and exerts surface compressive stresses after cooling to room temperature. The zirconia functional layer enhances the surface hardness, wear resistance, corrosion resistance, fracture toughness and chemical stability of the zirconia/alumina composite.

In another embodiment in present invention, a porous functional film is deposited on a ceramic material as a drug delivery vehicle, such as for medical device applications. For example, the porous coatings can be made by incorporating surfactants or templates into the functional film. Suitable porous structure generating agents include, but are not limited to, polymers, hydro-carbon materials, organic materials, porous generation agents, carbon powders, powders, fibers, etc, metal salts, and mixtures thereof. As a drug delivery vehicle, the drug or drugs can be directly loaded and encapsulated inside the pores of ceramics matrix by impregnating with a drug solution and/or polymer solution, individually, to control drug release profiles. The zirconia functional film that applies compressive stress on the surface of zirconia materials thus also acts as a protection film and drug delivery vehicle. Beneficial drugs, proteins and therapeutic agents that may be employed in the practice of the present invention include, but are not limited to, anti-thrombotic agents, anti-proliferative agents, anti-inflammatory agents, anti-migratory agents, agents affecting extracellular matrix production and organization agents, antineoplastic agents, anti-mitotic agents, anesthetic agents, anti-coagulants, vascular cell growth promoters, vascular cell growth inhibitors, bone growth factors, BMP, Bis-phosphonates cholesterol-lowering agents, vasodilating agents, proteins, DNA, and agents that interfere with endogenous vasoactive mechanisms. An example of a impurity metals, yield high purity final ceramic products. The colloidal gel monoliths have, however, very small pore structures and relatively low densities. Removal of the solvents from these open networks and the overall shrinkage in processing requires special care to avoid cracking. In addition, thermal processing must take into account high surface water and carbonaceous residues that can lead to bloating, residual bubbles or crystal formation if not properly removed. In order to overcome the high shrinkage problem of classical sol-gel processing, calcined ceramic powders or fibres (ceramic fillers) may be dispersed into sols to fabricate high performance composite sol-gel ceramics. The shrinkage of these bodies is decreased because of the presence therein of a significant amount of inert ceramic powders or fibers. The additional advantages of sol-gel processing for ceramic composites are fine scale mixing and low densification temperature, leading ultimately to improved properties. This composite sol-gel technology can be used to fabricate crack-free thick ceramic coatings, up to several hundred μm thick, on ceramic substrates.

In another embodiment, nano-size ceramic powders are used to fabricate the ceramic materials and functional ceramic film. Nano-ceramic powders are a necessary ingredient for many of the structural ceramics, electronic ceramics, ceramic coatings, and chemical processing and environmental related ceramics. For most advanced ceramic components, starting powder is a significant factor. The performance characteristics of a ceramic component are greatly influenced by precursor powder characteristics. Among the most important are the powder's chemical purity, particle size, size distribution, and the manner in which the powders are packed in the green body before sintering. Nano-powders can be compacted into ordered arrays, and the materials are sintered at reduced temperatures.

In another embodiment, processing agents are incorporated into the composition for make high density ceramic materials and coating forming high strength films. Processing agents said for this purpose include, but are not limited to, coupling agents, polymers, salts, metal oxides, and non-metal oxides.

### EXAMPLES

### Example 1

### Pure Zirconia film on High Strength Stabilized Zirconia Ceramics

Nano-size yttria stabilized zirconia powders were used to fabricate a ceramic substrate by cold isostatic pressing. The nano-size stabilized zirconia powders were mixed with an oil-water mixture, and then placed into the mold, and pre-pressed up to 10,000 psi. Nano-size pure zirconia powders were also mixed with an oil-water mixture, and homogenously sprayed 2 mm thick pure zirconia powder on the pre-pressed surface of ceramic materials, then pressed up to 100,000 psi. The cold pressed ceramic materials were sintered at 1500° C. for four hours. The pure zirconia film has the phase transformation from cubic/tetragonal to monoclinic structure with expansion during the cooling process. The volume increase in functional film induces the compressive stresses for enhancing fracture toughness, wear resistance, hardness, chemical stability, and biological properties.

### Example 2

### Pure Zirconia Film on High Strength Partially Stabilized Zirconia

The nano-size pure zirconia powders were used to make a functional film by co-hot pressing process. Nano-size pure zirconia powders were mixed with an oil-water mixture, and homogenously sprayed 2 mm thick pure zirconia powder on the surface of mold. The nano-size stabilized zirconia powders were mixed with an oil-water mixture, and then placed into the mold, and pre-pressed up to 10,000 psi, and then homogenously sprayed 2 mm thick pure zirconia powder on the pre-pressed surface of ceramic materials. The materials were sintered by hot isostatic presses (HIP) in an argon atmosphere or other gas mixtures heated up to 1300° C. and pressurized up to 100,000 psi. The pure zirconia film has the phase transformation from cubic/tetragonal to monoclinic structure with expansion during the cooling process. The volume increase in functional film induces the compressive stresses for enhancing fracture toughness, wear resistance, hardness, chemical stability, and biological properties. This technique can be directly used for making implantable medical device, such as hip and knee replacements

### Example 3

### The Zirconia Functional Film Prepared by Brushing Processing

Powders of nanocrystalline YSZ were synthesized by a sol-gel method. ZrOCl₂-8H₂O and Y₂O₃ were selected as precursors. Y₂O₃ was dissolved into a hot nitric acid to obtain yttrium nitrate solution, and ZrOCl₂-8H₂O were dissolved into the deionized water. These two solutions in a stoichiometric ratio were then mixed and stirred continuously until a homogenous solution was obtained. Citric acid and ethylene glycol were then added and stirred at 70° C. till gellation was completed. Then the gel was dried at 110° C. and calcined at different temperatures. Compaction was completed using a cubic-type high pressure equipment with six WC anvils. The powder was firstly compacted at 200 MPa, and then the green compact was loaded in a graphite sleeve heater, encapsulated in a cube die made of pyrophyllite, and then the residual room was filled with h-BN as heat-transmitting medium. High mechanical pressure was then applied. In this way, the samples were sintered under a high pressure of 4.5 GPa at different temperatures for a very short time.

The slurry for marking monoclinc film was prepared by dispersing monoclinic zirconia nanopowder (5-50 nm) into deionized water with 0.2 wt % of critic acid as the dispersion agents. The slurry was mixed by planetary ball mill for 20 min. The Monoclinic zirconia film (1 mm thick) was deposited to on YSZ green compact surface by brushing process, and then dried at 110° C. for 24 hours. The samples were fired at 1450° C. for 4 hours. The samples were used for evaluating the mechanical properties and chemical stability. The bending strength is 1600 MPa, the hardness is 1400 kg/mm², and fracture toughness is 16. The pure zirconia film has the phase transformation from Cubic/tetragonal to monoclinic structure with expansion during cooling process. The volume increase in functional film induces the compressive stresses for enhancing fracture toughness, wear resistance, hardness, chemical stability, and biological properties.

### Example 4

### The Functional Film on Al203/TiC/ZrO2 Nanocomposites

The TiC powder, alumina fiber, stabilized zirconia reactant powders were used as starting materials. The mixed powders were ball-milled in water-free ethanol for 24 h using alumina milling-media. The mixture of 80 wt % of zirconia nanopowders and 20 wt % of alumina powder was deposited on mold, and place the mixed powder in to mold, and then pre-press at 500 psi, and then deposited another layer of zirconia/alumina nano-powder. The pellets were hot-pressed at 1650° C. for 30 min in N₂ atmosphere with 25 MPa applied uniaxial pressure. The zirconia/alumina film had compressive stress for enhancing mechanical properties and preventing from the oxidation of TiC in the composite

Example 5

### Functional Film on Hot Press Femoral Head

Stabilized zirconia is used as a femoral head component in hip implants. High strength and high toughness allow the hip joint to be made smaller which allows a greater degree of articulation. The ability to be polished to a high surface finish also allows a low friction joint to be manufactured for articulating joints such as the hip. The chemical inertness of the material to the physiological environment reduces the risk of infection. For this reason, only zirconium manufactured from low radioactivity materials can be used in this application. However, the aging issue of low temperature degradation of zirconia ceramic femoral head caused the recall on Aug. 14, 2001 because it fractured at a higher rate than expected in some patients 13 to 27 months after being implanted. The present example illustrated the functional film to barrier layer for preventing from low temperature degradation and enhancing the mechanical properties.

The zirconia ceramic femoral head was made by hot pressing stabilized zirconia nanopowder, and deposit a layer monoclinic zirconia nanopowder on the surface of zirconia femoral head by spraying process, drying at 110° C., and fired at 1450° C. 1 mm thick monoclinic zirconia film with compressive stress on the stabilized zirconia femoral head enhances the wear resistance, surface hardness, fracture toughness, and chemical stability.

### Example 6

### Dental Implant with Double Layer Coatings

Nano-size cerium oxide stabilized zirconia powders were used to fabricate a ceramic substrate by cold isostatic pressing. The nano-size stabilized zirconia powders were mixed with an oil-water mixture, and then placed into the mold, and pre-pressed up to 100,000 psi. The pre-formed zirconia was machined as a screw dental implant. The first layer of pure zirconia was made by dipping the zirconia implant into zirconia slurry (the preparation was described in Example 3), and then spinning at 1000 rpm, and then drying at 110° C. for 24 hours. The second layer is zirconia/hydroxyapatite porous film. The slurry was made by dispersing 40 g nanopower zirconia (20 nm), 40 g of hydroxyapatite nanopowder (60 nm), and 20 g polymer sphere (2-10 um) into 1 liter water with 0.01 wt % of critic acid as dispersion agent. The slurry was ball milled for 24 hours. The second layer was deposited on surface of first layer by spraying process, and then drying at 110° C. for 24 hours, and then firing at 1400° C. for 4 hours. The first layer of monoclinic zirconia layer is dense layer (99% of sintering) with compressive stress for enhancing mechanical properties and chemical stability, and the second layer is porous layer with pore size 1-5 micrometer and 50 vol % of porosity as drug delivery vehicle. The bioactive agents were encapsulated into porous structure by placing the porous implant into bisphosphonate solution for 5 hours. The bioactive agent bisphosphonate was loaded into porous structure by absorption and impregnation processes.

### Example 7

### Drug Encapsulated in Bioceramic Composite with Biopolymer Diffusion Barrier

As described in Example 6, different drugs were encapsulated into the polymer and porous structure. In order to add further controls for drug release profile, e.g. to further slow down the drug release rate, a functional diffusion barrier was deposited on the surface of the porous layer. In this particular, a polymer layer with anti-inflammatory drugs was deposited on the dental implant surface by spin-coating. The drug eluting profile can be controlled by engineering porous structure, biopolymer content, and degradation of biopolymer.

### Example 8

### Light Weight Armor Ceramics

Armor is protective covering used to prevent damage from being inflicted to an individual or a vehicle through use of direct contact weapons or projectiles, usually during combat, or from damage caused by potentionally dangerous environment. Currently, ceramic tiles are popularly used for armor plates; however, the additional armor has added significantly more weight. The present example show the process for making lightweight alumina armor plates. The mixture 80 wt % of pro-forming pure zirconia particle (20-40 micrometer) and nanosize alumina was used as raw materials of functional ceramic films. The testing samples for bending strength was prepared by depositing layer of 1 mm thick of the pure zirconia and alumina on bottom of mold and filling 20 mm thick of nanosize alumina powder, and then pre-pressing 1000 psi, depositing another 1 mm thick of the mixture of zirconia and alumina, and finally pressing 100,000 psi. The control samples of alumina were made by filling 22 mm thick alumina powder and then pressing 100,000 psi. All the samples were fired at 1450 for 2 hours. 3-point bending strength for control samples of alumina are 300-400 MPa and for the samples with functional ceramic film are 700-1000 MPa. The bending strength of alumina is significantly increased by applying the functional ceramic film on alumina ceramics. The weight of armor plates are reduced by 50%.

What is claimed is:

1. A method for making a functional ceramic film on a ceramic material, comprising:
providing a ceramic material;
forming at least one layer of functional ceramic film exerting a compressive stress;
covering at least a portion of a surface of said ceramic material with said layer of functional ceramic film.

2. The method of claim 1, wherein the step of forming said functional ceramic film comprises:
forming a functional ceramic film comprising at least 10 weight percentage of substantially pure zirconia, with phase transformation from tetragonal/cubic phases at high temperature to monoclinic phase at room temperature to lead to volume expansion and compressive stress.

3. The method of claim 2, wherein the step of forming said functional ceramic film further comprises:
said substantially pure zirconia from the group consisting of monoclinic zirconia, un-stablizied zirconia, and mixtures thereof.

4. The method of claim 3, wherein the step of providing said ceramic material comprises:
selecting said ceramic material from the group consisting of:
metal oxide ceramics;
metal salt ceramics;
non-oxide ceramics;
ceramic composites; and
mixtures thereof.

5. The method of claim 3, wherein the step of providing said ceramic material comprises:
selecting said ceramic material from the group consisting of:
partially stabilized zirconia;
zirconia composites;
zirconia compounds; and
mixtures thereof.

6. The method of claim 1, wherein the step of placing said layer of functional ceramic film on said ceramic material comprises:
depositing said functional ceramic film on said ceramic material and then sintering said film on said ceramic material.

7. The method of claim 1, wherein the step of placing said functional ceramic film on said ceramic material comprises:
depositing said ceramic film on a un-sintered ceramic substrate and then co-sintering said film and ceramic substrate.

8. The method of claim 1, wherein said functional ceramic film includes at least one secondary phases so as to form a composite coating.

9. The method of claim 1, wherein the step of placing said at least one functional ceramic film on said ceramic base material comprises:
placing a plurality of overlying layers of functional ceramic film on said ceramic base material.

10. The method of claim 9, wherein a first one of said plurality of layers has a lower compressive stress therein than a second one of said layers.

11. The method of claim 10, wherein said second layer comprises a bioactive coating.
